(19) United States
(12) Patent Application Publication
(10) Pub. No.: US 2026/0286938 A1
(43) Pub. Date: Sep. 24, 2026

(54) TRANSMISSION SHAFT FOR A PLANETARY TRANSMISSION

(71) Applicant: Flender GmbH, 46395 Bocholt (DE)

(72) Inventors: SEBASTIAN REISCH, Bocholt (DE); CHRISTIAN KÖNIG, Bocholt (DE); MARCO RÜHL, Bocholt (DE); MICHAEL VENNEMANN, Bocholt (DE); CHRISTOF SIGLE, Hallwang (AT); ALEXANDER KARI, Fuschl am See (AT)

(73) Assignee: Flender GmbH, 46395 Bocholt (DE)

(21) Appl. No.: 19/474,319

(22) PCT Filed: Apr. 5, 2024
(86) PCT No.: PCT/EP2024/059326

§ 371 Date: Oct. 10, 2025

(30) Foreign Application Priority Data
Apr. 14, 2023 (EP) 23167953.1

(51) Int. Cl. F03D 15/10; F16D 3/12; F16H 57/00; F16H 57/02; F16H 57/021; F16H 57/08; G06F 30/15

(52) U.S. Cl. CPC F03D 15/101; F16D 3/12; F16H 57/0006; F16H 57/0018; F16H 57/021; F16H 57/08; G06F 30/15; F05B 2260/40311; F05B 2260/84; F16H 2057/02034; F16H 2057/02078

(57) ABSTRACT

A gearbox shaft includes a first coupling point for introducing a torque which is transmitted by a first shaft region along an axial torque flow and by a second shaft region counter to the first shaft region and which is transmitted by a disk region between the first and second shaft regions along a radial torque flow. A second coupling point discharges the torque. A path of a torque flow from the first coupling point to the second coupling point is formed, with a sum of axial components being greater than an axial spacing between the first and second coupling points. The first and second shaft regions overlap in a common axial sub-region in which a freely oscillating shaft end is formed in which the torque flow flows at different radil in opposite axial directions, with the disk region defining an axial end portion as part of the shaft end.

The invention relates to a gearbox shaft, in particular a sun shaft, for a planetary gearbox, which can be used for torque transmission. In addition, the invention relates to a planetary stage, in particular a planetary gearbox, having such a gearbox shaft, to a wind turbine gearbox having such a planetary stage, to a drivetrain having such a wind turbine gearbox, to a use of such a gearbox shaft and to a data agglomerate for the additive manufacturing and/or simulation of such devices.

DE 19926301 A1 discloses, in the case of a wind turbine gearbox for a wind turbine, allowing a sun gear of a planetary gearbox to mesh helically with planet gears of the planetary gearbox in order to reduce or avoid oscillations and noise emissions.

US 2010/133854 A1 discloses a gearbox shaft configured as a sun shaft of a wind turbine gearbox, in the case of which a torque introduced at sun shaft toothing flows in a common sub-region at two different radii in different axial directions as far as a fastening to a rotor carrier of a rotor of a generator, wherein a protruding shaft end, provided radially within the rotor, of the gearbox shaft is mounted so as to be radially fixed against movement via a screwed-on cover,

DE 296 09 794 U1 discloses a gearbox shaft that is configured as a sun shaft of a wind turbine gearbox and protrudes, by way of its shaft end, into a generator, where the shaft end is fastened, using a cover that is fitted on by means of spline toothing, to a rotor carrier of a rotor of the generator, which is mounted so as to be radially fixed against movement on a generator housing using two rolling bearings that are clearly spaced apart from one another.

EP 2 461 030 A2 discloses a gearbox shaft that is configured as a sun shaft of a wind turbine gearbox and protrudes, by way of its shaft end, into a generator, where the shaft end is connected, using spline toothing, to a hub, which is connected to a rotor carrier of a rotor of the generator and is mounted partially in a common axial region with the gearbox shaft so as to be radially fixed against movement on a generator housing using two rolling bearings that are clearly spaced apart from one another.

WO 2011/056344 A1 discloses a gearbox shaft configured as a sun shaft for a double planetary set, arranged in succession in the axial direction, of a wind turbine gearbox, to which sun shaft a shaft protruding into a generator is fastened, to which shaft a coupling is fastened using spline toothing, it being possible to use said coupling to couple a rotor of the generator.

There is a constant need to reduce disturbing oscillations in planetary gearboxes.

The object of the invention is to specify measures that enable disturbing oscillations in a planetary gearbox to be reduced.

The object is achieved by means of a gearbox shaft having the features of claim 1, a planetary stage having the features of claim 10, a wind turbine gearbox having the features of claim 11, a drivetrain having the features of claim 12, a use having the features of claim 14 and a data agglomerate having the features of claim 15. Preferred configurations, which may in each case individually or in combination represent an aspect of the invention, are specified in the dependent claims and the following description. If a feature is presented in combination with another feature, this serves only for simplified illustration of the invention and is in no way intended to mean that this feature cannot also be a development of the invention without the other feature, the scope of protection of the invention being defined by the independent claims.

One aspect of the invention relates to a gearbox shaft, in particular a sun shaft, for a planetary gearbox, having a first coupling point, in particular toothing, for introducing a torque and a second coupling point for discharging the torque, in particular to a rotor shaft of a generator, wherein a path of a torque flow extending from the first coupling point to the second coupling point is formed and the axial components of the path along which the torque flow flows are greater than an axial spacing between the first coupling point and the second coupling point, wherein a freely oscillating shaft end is formed in a common axial sub-region in which the torque flow flows at different radii in opposite axial directions.

Between two points defining the spacing between the coupling points, through which the torque flow also passes, the sum of the axial components of the torque flow, which the torque flow flows along the specified path for the torque flow, is greater than the axial spacing between the coupling points. The torque flow through the gearbox shaft does not take the shortest path between the first coupling point and the second coupling point. Instead, the torque flow can flow back, at least in the common sub-region, to a part in one axial direction and, radially offset to this part, in the opposite axial direction again. For example, the torque flow can be guided from the first coupling point along a first diameter and past the second coupling point, subsequently be deflected to a second diameter different from the first diameter and pass along the second diameter in the opposite direction to the torque flow on the first diameter past the second coupling point. The path of the torque flow can have a serpentine, meandering and/or zigzag-shaped course between the coupling points, resulting in a detour for the torque flow in comparison to the spacing between the coupling points. Even in the case of a very compact design of the gearbox having the gearbox shaft according to the invention, the deliberate detour for the torque flow enables the effective length along which the torque flow must flow between the first coupling point and the second coupling point to be significantly increased. The increased effective length results in a reduced stiffness of the gearbox shaft and thus in a significantly reduced natural frequency of the overall system, especially the wind turbine gearbox and/or drivetrain of a wind turbine in which this gearbox shaft is used. It is also possible to configure the gearbox shaft to be particularly torsionally flexible and/or pliable. This can prevent resonance oscillations from building up, and therefore damage and/or unnecessary noise emissions can at least be reduced.

Oscillation dampers and/or oscillation absorbers that would otherwise be required can be eliminated, and therefore the installation space requirement and the manufacturing costs can be reduced. The function of an oscillation damper and/or an oscillation absorber can be formed by the freely oscillating shaft end in the common axial sub-region. The freely oscillating shaft end can oscillate in the radial direction within the context of its elastic deformation capacity in a manner comparable to a rod fastened at one end, wherein the natural frequency of this oscillation can be defined by way of the extent of the axial protrusion of the freely oscillating shaft end. This makes it possible to attenuate expected oscillations in the overall system, so that, for example, oscillations induced by an electromagnetic interaction between a rotor and a stator of an electric machine can be attenuated when the rotor shaft of the rotor is connected to the second coupling point. The extended path of the torque flow enables the stiffness and natural frequency of an overall system capable of oscillation having the gearbox shaft to be reduced, thereby making it possible to reduce disturbing oscillations in a planetary gearbox.

For example, in one exemplary embodiment, a drivetrain of a wind turbine can be provided with a so-called medium-speed (“midspeed”) drivetrain concept, in the case of which a generator of the wind turbine is intended to be operated at a speed of between 100 rpm and 1000 rpm and a wind turbine gearbox interposed between the wind turbine rotor and the generator is intended to provide a gear ratio of between 10 and 80. In particular, it is possible that a gearbox shaft, configured as a conventional sun shaft, of a planetary stage and/or a planetary gearbox of the wind turbine gearbox would lead to a natural frequency of approximately 200 Hz for the drivetrain, which would thus fall within the range of possible tooth meshing frequencies of the wind turbine gearbox, and therefore resonance effects cannot be safely excluded, whereas a gearbox shaft according to the invention configured as a sun shaft can be used in the identical installation situation to achieve a natural frequency of 70 Hz for the drivetrain, which is safely outside expected tooth meshing frequencies of the wind turbine gearbox and can ensure supercritical operation. In particular in a final gear stage of the wind turbine gearbox, which is to be connected to the rotor shaft of the generator, it is possible to achieve a clear shift of the critical natural frequencies or eigenmodes. This makes it possible to at least reduce the occurrence of resonance oscillations during operation and/or noise emissions with a low design outlay.

The gearbox shaft is in particular dimensioned for transmitting all of the torque that occurs. The gearbox shaft can preferably be used as an input shaft and/or as an output shaft of a planetary gearbox, for example as a planet carrier shaft and/or sun shaft. If the gearbox shaft is provided in the power direction of the torque flow between two planetary stages, the gearbox shaft can preferably be used both as a sun shaft for one planetary stage and as a planet carrier shaft for the other planetary stage. Preferably, the gearbox shaft is configured and/or dimensioned in order to introduce all of the torque that occurs into the planetary stage and/or into the planetary gearbox and/or to discharge it from the planetary stage and/or from the planetary gearbox by rotating about a main axis of rotation of a planetary stage and/or planetary gearbox.

It is possible to distinguish different regions of the gearbox shaft, which is in particular a multi-part gearbox shaft. The gearbox shaft can have a first shaft region for transmitting the torque along an axial torque flow, a second shaft region for transmitting the torque along an axial torque flow counter to the first shaft region, and a disk region for transmitting the torque between the first shaft region and the second shaft region along a radial torque flow, wherein the first shaft region and the second shaft region, when viewed in the axial direction, overlap in the common axial sub-region. The path of the torque flow is provided at different radii in the first shaft region and in the second shaft region. The disk region can define an axial end portion that is part of the freely oscillating shaft end, wherein in particular the disk region experiences the maximum amplitude of the oscillation occurring in the region of this common axial sub-region. Particularly preferably, a third shaft region for transmitting the torque along an axial torque flow counter to the second shaft region and a further disk region connecting the second shaft region to the third shaft region is provided in order to transmit the torque between the second shaft region and the third shaft region along a radial torque flow. The further disk region can define an axial end portion that is likewise part of a freely oscillating shaft end, wherein in particular the further disk region experiences the maximum amplitude of the oscillation occurring in the region of this common axial sub-region. This enables the axial extent of the axial sub-region and of the freely oscillating shaft end to be increased with a compact design of the overall system. If a third shaft region is provided and thus three shaft regions are provided at three different radil, it is even possible to form two different freely oscillating shaft ends. The respective shaft region can be formed in each case by a separately formed (hollow) shaft, which are directly or indirectly connected to one another, in particular screw-fastened or pinned, to form the multi-part gearbox shaft, wherein in particular the respective connection is configured as a connection that is fixed against movement in the radial direction and in the axial direction and in the circumferential direction. In particular, all of the shaft regions of the gearbox shaft are tubular and/or configured as a hollow shaft. Preferably, the axial extent I of the freely oscillating shaft end in the common sub-region is greater than an inner diameter dᵢ of the radially smallest shaft region within the common sub-region, wherein in particular 0.1≤dᵢ/I<1.0, preferably 0.2≤dᵢ/I<0.9, further preferably 0.3≤dᵢ/I<0.7 and particularly preferably 0.4≤dᵢ/I<0.5.

The torque flow that flows from the first coupling point to the second coupling point essentially comprises the entire torque introduced at the first coupling point. Any frictional moments and/or bearing torques that may occur are not taken into account in this case. In particular, each region of the gearbox shaft, in particular all of the shaft regions and all of the disk regions in the path of the torque flow between the first coupling point and the second coupling point, is designed for the transmission of the maximum torque provided at the first coupling point. Bearings intended for mounting the gearbox shaft, such as rolling bearings and/or plain bearings, are considered not to be torque transmitting and not to be part of the gearbox shaft, and therefore the bearings are considered not to be part of the path for the torque flow through the gearbox shaft.

In particular, the gearbox shaft only has exactly the two coupling points through which the torque flow between the gearbox shaft and another gearbox component is exchanged. A third coupling point, which can be used to form a power-split gearbox, for example a summation gearbox or transfer gearbox, is avoided. This essentially enables the entire torque flow to flow via the two coupling points along the designated power direction via rotating gearbox components, i.e. apart from any bearing and supporting forces on radial and/or axial bearings for mounting the gearbox shaft and/or brakes. A closed force path via fixed components, in particular via a housing, is not taken into account when considering the torque flow. As a rule, the associated gearbox is designed to transmit over 95%, in particular over 98%, of the input power along the torque flow to an output shaft leaving the gearbox. Preferably, when viewed from the first coupling point, the gearbox shaft is unmounted beyond the second coupling point, so that the gearbox shaft can oscillate freely at least from the second coupling point, as a result of which the natural frequency of the overall system capable of oscillation can be displaced and/or disturbing frequencies can be eliminated or at least attenuated. Particularly preferably, the entire gearbox shaft is unmounted, wherein in particular the gearbox shaft is mounted only indirectly via the mounting of the torque-transmitting component upstream in the torque flow along the power direction and/or of the torque-transmitting component downstream in the torque flow along the power direction.

The first coupling point can connect a torque-transmitting component upstream in the torque flow along the power direction. In particular if the gearbox shaft is configured as a sun shaft, the first coupling point can be configured as toothing, wherein the toothing can represent the toothing of a sun gear, which is in particular connected in one piece, or is designed as toothing, in particular involute splines, for the rotationally conjoint connection, in particular via spline toothing, of the sun gear to the gearbox shaft configured as a sun shaft. For example, the first coupling point can be configured as a flange of a flange connection, which enables releasable fastening to the upstream component. It is also possible that the first coupling point forms an unreleasable connection to the component configured in particular as a planet carrier of an upstream planetary stage. The gearbox shaft can be coupled to the upstream component, for example, by means of welding, soldering, overmolding or even by means of a one-piece configuration. In the case of a one-piece configuration, the gearbox shaft protrudes from the upstream component, in particular a carrier side plate of a planet carrier, by a significantly larger diameter in the axial direction, wherein the first coupling point of the gearbox shaft is formed on the axial side of the component with the larger diameter on the side of the gearbox shaft. The first coupling point can also be configured as a tongue/groove connection, in particular a feather keyway connection or as (spur) gear toothing or a press fit, thus resulting in a recognizable axial extent for the first coupling point.

A torque-transmitting component downstream in the torque flow along the power direction can be coupled to the second coupling point of the gearbox shaft. The downstream torque-transmitting component is in particular a rotor shaft of a generator to which a rotor of an electric machine is connected for conjoint rotation therewith. The rotor has in particular permanent magnets, which can interact electromagnetically with electromagnets of a stator of the electric machine. The rotor shaft connected to the rotor extends at least partially within the generator, preferably radially within a generator housing. The rotor shaft can preferably extend in one piece as far as the gearbox of the gearbox shaft and as a result can simultaneously form a gearbox output shaft that protrudes from the gearbox, in particular from a gearbox housing. The rotor shaft is mounted in particular on the generator housing, on the gearbox housing and/or on an intermediate piece or intermediate wall between the gearbox and the generator, preferably via a rolling bearing. Alternatively, the rotor shaft can be releasably connected to a gearbox output shaft protruding, coaxially to the rotor shaft, from the gearbox, for example via a tongue/groove connection, a flange connection and/or a shrink disk. In this case, it is the output shaft that is mounted using a separate bearing, in particular a rolling bearing, on the gearbox housing on the generator housing and/or on an intermediate piece or intermediate wall between the gearbox and the generator and forms the torque-transmitting component downstream along the power direction for the gearbox shaft. Alternatively, the torque-transmitting component downstream in the torque flow along the power direction can be configured as part of a planetary gearbox, in particular a sun gear or planet gear. Preferably, the torque flow from the first coupling point to the second coupling point passes exclusively via unmounted axial regions of the gearbox shaft. Direct or indirect mounting of the gearbox shaft can be provided exclusively outside those axial areas of the gearbox shaft that are not intended for the torque flow flowing in the power direction. In this case, a directly mounted shaft, the mounting position of which the torque flow passes in the power direction, is no longer part of the gearbox shaft, but instead a separate shaft that is different from the gearbox shaft.

The second coupling point can be configured as toothing, in particular involute splines, to which corresponding toothing of the output shaft of the gearbox and/or a rotor shaft of the generator can be coupled for conjoint rotation therewith, in particular via spline toothing. In principle, it is possible that the toothing of the second coupling point can be used as toothing for a planet carrier and/or a sun gear and/or planet gears of a planetary stage and/or for spur gear toothing. The toothing of the second coupling point can be straight-cut or helical. Preferably, the toothing is crowned in order to facilitate assembly and/or to allow the gearbox shafts to tilt within predetermined limits. Preferably, the second coupling point is configured as a flange, so that the gearbox shaft can be screw-fastened to an output shaft of the gearbox and/or a rotor shaft of the generator. As a result, unnecessary wear can be avoided and the stiffness and the natural frequency of the drivetrain can be further reduced. Alternatively, the second coupling point can also be configured as a tongue/groove connection, in particular a feather keyway connection or as (spur) gear toothing or a press fit, thus resulting in a recognizable axial extent for the second coupling point.

In particular, for the path W of the torque flow and the spacing A between axial sides facing away from one another of the first coupling point and the second coupling point, 1.1≤W/A≤12.0, in particular 1.5≤W/A≤6.0, preferably 2.0≤W/A≤4.0 and particularly preferably 2.5≤W/A≤3.0. This results in an intentionally provided detour of the length of approximately W−A for the torque flow with respect to the spacing A between the coupling points. In particular, the gearbox shaft protrudes by a distance of approximately (W−A)/2 from the second coupling point in an axial direction facing away from the first coupling point. The length of this detour can be suitably dimensioned depending on the installation space situation and the speeds occurring, in order to set the natural frequency of the drivetrain within a range that is far enough away from the occurring excitation frequencies, in order to at least reduce or even avoid resonance effects and noise emissions.

Preferably, a total extent L of the gearbox shaft is greater than the spacing A between axial sides facing away from one another of the first coupling point and the second coupling point, wherein 1.01≤L/A≤6.0, in particular 1.05≤L/A≤4.0, preferably 1.10≤L/A≤2.0 and particularly preferably 1.25≤L/A≤1.75. This enables the gearbox shaft to protrude by a distance of L−A from the second coupling point in an axial direction facing away from the first coupling point. The torque flow can, in particular, experience an intentionally provided detour of the length of approximately 2(L−A) with respect to the spacing A between the coupling points. The length of this detour can be suitably dimensioned depending on the installation space situation and the speeds occurring, in order to set the natural frequency of the drivetrain within a range that is far enough away from the occurring tooth meshing frequencies, in order to at least reduce or even avoid resonance effects and noise emissions.

When viewed from the first coupling point, the gearbox shaft can protrude by a distance S beyond the second coupling point, wherein in particular substantially S=L−A and/or S=(W−A)/2. In particular, the gearbox shaft can protrude in an unmounted manner. With respect to a width B in the axial direction of the gearbox shaft of the first coupling point, which is designed in particular as toothing, it is possible that 0.5≤S/B≤10.0, in particular 1.0≤S/B≤8.0, preferably 1.5≤S/B≤5.0 and particularly preferably 2.0≤S/B≤4.0.

Particularly preferably, the gearbox shaft has a first shaft, a second shaft and in particular at least one intermediate shaft, wherein the first coupling point is directly connected to the first shaft, and the second coupling point is directly connected to the second shaft, which is different from the first shaft and is connected directly or indirectly, in particular via the at least one intermediate shaft, for conjoint rotation with the first shaft, wherein the first shaft and the second shaft, when viewed in the radial direction, at least partially overlap in a common axial region, wherein, in particular, the at least one intermediate shaft is arranged within the common axial region in the radial direction between the first shaft and the second shaft in the radial direction. The first shaft and the second shaft, as well as the at least one optionally provided intermediate shaft, can be fitted one inside the other in the axial direction, in particular coaxially, resulting in radial nesting of the gearbox shaft, in which the individual (partial) shafts of the gearbox shaft share a common axial region on different non-interfering diameters. The common axial region can in particular comprise the sub-region of the gearbox shaft in which the freely oscillating shaft end is formed. This enables the torque flow to flow over the individual shafts in a zigzag, so that a large effective length for the gearbox shaft results from a small installation space requirement. An effective length desired for a certain natural frequency of the overall system capable of oscillation can be assembled in a radial direction with a sufficient installation space requirement via a plurality of nested hollow shafts, wherein in particular two, three, four or even more intermediate shafts configured as hollow shafts can be provided in this case.

In particular, the first shaft has an outer diameter d1 and the second shaft has an outer diameter d2, wherein, for a ratio V defined as d1/d2 or d2/d1, 1.01≤V≤5.0, in particular 1.05≤V≤3.0, preferably 1.10≤V≤2.0 and particularly preferably 1.25≤V≤1.5. The diameters of the shafts differ sufficiently greatly in that at least one of the shafts can be configured as a hollow shaft and, apart from the rotationally conjoint connection, can receive this shaft in its interior without abutment against the other shaft.

Preferably, the connection, which is in particular configured as spline toothing or a flange connection, of the first shaft for conjoint rotation with the second shaft or with the intermediate shaft in the axial direction is formed outside an axial region of the first coupling point and the second coupling point and outside an axial interspace between the first coupling point and the second coupling point. The connection of the first shaft for conjoint rotation with the second shaft or with the intermediate shaft immediately following in the direction of the torque flow can thus be formed in a region protruding from the second coupling point in a direction facing away from the first coupling point. The additional effective length of the gearbox shaft for the torque flow makes it possible to avoid or at least reduce unnecessary stiffening of the gearbox shaft as a result of the rotationally conjoint connection.

Particular preferably, the first shaft is formed axially adjacent to the first coupling point and/or the second shaft is formed axially adjacent to the second coupling point and in each case is formed as a hollow shaft with a wall thickness s axially adjacent to the rotationally conjoint connection, wherein, with respect to a length l of the first shaft and/or the second shaft outside the respective coupling point and outside the rotationally conjoint connection, 0.01≤s/l≤0.50, in particular 0.02≤s/l≤0.25, preferably 0.03≤s/l≤0.15 and particularly preferably 0.05≤s/l≤0.10. For the consideration of the ratio s/l, only the axial regions of the first shaft and second shaft configured as a hollow shaft are considered in each case, said axial regions being different from regions that may axially overlap with the coupling points and/or rotationally conjoint connection. This wall thickness is large enough to be able to withstand the mechanical loads that occur during operation. At the same time, this wall thickness makes it possible to configure the gearbox shaft to be torsionally flexible and/or pliable. In addition, it is easily possible to fit the first shaft and the second shaft inside one another with a small radial installation space requirement.

In particular, provision is made for an elastically deformable damper element and/or an, in particular switchable and/or controllable, coupling element that contact(s) the first shaft and the second shaft or the intermediate shaft and/or the second shaft and the intermediate shaft. The damper element can be produced in particular from an elastomer and/or an artificial or natural rubber, in particular synthetic rubber. The damper element can at least limit relative tilting of the respective contacted shaft in the manner of a spacer. At the same time, the damper element, which preferably has a progressive-rate spring characteristic, can allow elastic deformation, in particular torsion and/or bending of the shaft, to a sufficient extent. The coupling element can be a rigid coupling, for example a steel multi-plate coupling. In particular, the coupling element can be configured as an elastic coupling, which allows tilting and/or rotation and/or an axial offset at least within a predefined limited extent with elastic deformation of an elastic element. The damper element and/or the elastic coupling element can provide deliberate frictional damping, which makes it easier to pass through a resonance range of the gearbox shaft when starting up and limits resonance oscillations that occur. After passing through the resonance range, the effect of the damper element and/or of the elastic coupling element can be small enough as to have a negligible effect on the reduction in the stiffness of the gearbox shaft. Particularly preferably, the damper element and/or the coupling element can be switched, so that the damping and/or spring properties can be changed by active switching. This makes it possible, for example, to provide stronger frictional damping for the start-up process, it being possible to reduce or even deactivate said damping during regular operation. Within critical speed ranges, the engaged damping can avoid damage to gearbox components, while outside critical speed ranges, the damper element and/or the coupling element can be spared and unnecessary power losses due to frictional effects can be avoided. The switching can, for example, take place automatically in response to a sensor signal and/or in response to a switching element that can be actuated by centrifugal forces.

Preferably, electrical insulation is formed between the first coupling point and the second coupling point within the torque flow, wherein in particular the second shaft and/or a/the intermediate shaft are/is produced entirely or at least in certain portions from an electrically insulating material. The electrically insulating material, in particular non-conductive material, that acts as an electrical insulator provides a sufficiently effective dielectric that, even at the narrowest point between electrically conductive components of the gearbox shaft, a voltage flashover along the torque flow and/or transverse to the torque flow can be safely avoided during regular operation of the wind turbine. Currents and/or stray or leakage currents of the generator induced in the gearbox shaft by the generator can at most reach a point upstream of the sub-region of the generator shaft produced from the electrically insulating material. Positioning the electrically insulating material inside the gearbox shaft therefore makes it possible to protect a region affected by electrical voltages and/or electrical currents.

Another aspect relates to a planetary stage, in particular a planetary gearbox, having a gearbox shaft, which is in particular designed as a sun shaft and can be designed and developed as described above, wherein the first coupling point is preferably arranged in a common axial region with planet gears and/or a ring gear of the planetary stage and the second coupling point is arranged so as to be axially spaced apart from the planet gears and/or the ring gear. Alternatively, in particular in a reduction stage, the second coupling point can be arranged in a common axial region with planet gears and/or a ring gear of the planetary stage, while the first coupling point is arranged so as to be axially spaced apart from the planet gears and/or the ring gear. The gearbox shaft is in particular dimensioned for transmitting all of the torque that occurs. The gearbox shaft can preferably be used as an input shaft and/or as an output shaft of the planetary gearbox, for example as a planet carrier shaft and/or sun shaft. The gearbox shaft can, in particular by rotating about a main axis of rotation of the planetary stage, introduce all of the torque that occurs into the planetary stage and/or discharge it from the planetary stage. The extended path of the torque flow enables the stiffness and natural frequency of the drive train having the planetary stage to be reduced, thereby making it possible to reduce disturbing oscillations in a planetary stage, in particular a planetary gearbox.

Another aspect relates to a wind turbine gearbox for speed conversion in a drivetrain of a wind turbine, having at least one planetary stage, which can be designed and developed as described above, and a gearbox housing, wherein in particular the gearbox housing, when viewed in the radial direction of the gearbox shaft, completely or only partially covers the gearbox shaft, wherein preferably the gearbox housing covers both the first coupling point and the second coupling point of the gearbox shaft. In particular, part of the gearbox shaft of the planetary stage can protrude from the gearbox housing on the generator side, while both the first coupling point and the second coupling point are arranged within the gearbox housing. The extended path of the torque flow enables the stiffness and natural frequency of the drive train having the planetary stage of the wind turbine gearbox to be reduced, thereby making it possible to reduce disturbing oscillations in a wind turbine gearbox.

Another aspect relates to a drivetrain for a wind turbine, having a wind turbine gearbox, which can be designed and developed as described above, for converting a torque that can be introduced by a wind rotor and a generator, which is coupled to the wind turbine gearbox, for generating electrical energy from the torque flow introduced by means of the wind turbine gearbox, wherein, particular, the entire torque flow introduced into the generator passes via the gearbox shaft. The extended path of the torque flow enables the stiffness and natural frequency of the drive train to be reduced, thereby making it possible to reduce disturbing oscillations in a wind turbine gearbox.

In particular, it is provided that part of the gearbox shaft of the wind turbine gearbox protrudes into the generator and the first coupling point is provided in the wind turbine gearbox, wherein the second coupling point is provided within the wind turbine gearbox or within the generator. If the second coupling point is provided within the wind turbine gearbox, the gearbox shaft can be fastened to the output shaft of the wind turbine gearbox and/or the rotor shaft of the generator on the gearbox side, i.e. facing toward the first coupling point and/or between the first coupling point and a rotor or rotor carrier of the generator. If the second coupling point is provided within the generator, the gearbox shaft can be fastened to the output shaft of the wind turbine gearbox and/or the rotor shaft of the generator on the generator side, i.e. facing away from the first coupling point. For example, the second coupling point is fastened to a generator-side axial end of the generator shaft, in particular via a flange connection. The second coupling point can also be provided on a generator-side axial end of the output shaft, so that the generator shaft and/or the rotor carrier can be connected to the second coupling point on the generator side. This allows for different assembly options and/or assembly sequences, so that the drivetrain can be optimized for better serviceability while simplifying assembly.

Preferably, for a natural frequency f of the drivetrain, 10 Hz≤f≤150 Hz, preferably 20 Hz≤f≤100 Hz, more preferably 30 Hz≤f≤80 Hz and particularly preferably 40 Hz≤f≤75 Hz. In particular if the gearbox shaft is provided in a final gear stage of the wind turbine gearbox, which is to be connected to the rotor shaft of the generator, it is possible to achieve a clear shift of the critical natural frequencies or eigenmodes. This makes it possible to at least reduce the occurrence of resonance oscillations during operation and/or noise emissions with a low design outlay.

A further aspect relates to a wind turbine for generating electrical energy from wind power, having a drivetrain, which can be designed and developed as described above, and a wind rotor connected to the input side of the wind turbine gearbox for introducing a torque generated by wind power at the wind rotor. The extended path of the torque flow enables the stiffness and natural frequency of the wind turbine to be reduced, thereby making it possible to reduce disturbing oscillations in a wind turbine.

Particularly preferably, for a natural frequency f of the wind turbine, 10 Hz≤f≤150 Hz, preferably 20 Hz≤f≤100 Hz, more preferably 30 Hz≤f≤80 Hz and particularly preferably 40 Hz≤f≤75 Hz. In particular if the gearbox shaft is provided in a final gear stage of the wind turbine gearbox, which is to be connected to the rotor shaft of the generator, it is possible to achieve a clear shift of the critical natural frequencies or eigenmodes. This makes it possible to at least reduce the occurrence of resonance oscillations during operation and/or noise emissions with a low design outlay, wherein the expected excitation frequencies that can be generated by the wind rotor are also taken into consideration with the entire wind turbine as the considered system capable of oscillation. Preferably, the expected excitation frequencies that can be generated by a nacelle in which the drivetrain is accommodated and/or by a tower on top of which the nacelle is provided, can be taken into consideration.

Another aspect relates to a use of a gearbox shaft, which can be designed and developed as described above, in a planetary gearbox for the purpose of reducing audible structure-borne noise and/or airborne noise and/or resonance oscillations. The planetary gearbox is, in particular, part of a planetary stage, which can be designed and developed as described above, and/or part of a wind turbine gearbox, which can be designed and developed as described above, and/or part of a drivetrain, which can be designed and developed as described above, and/or part of a wind turbine, which can be designed and developed as described above. The gearbox shaft is in particular used for transmitting all of the torque that occurs. The gearbox shaft can preferably be used as an input shaft and/or as an output shaft of the planetary gearbox, for example as a planet carrier shaft and/or sun shaft. The gearbox shaft can, in particular by rotating about a main axis of rotation of the planetary gearbox, introduce all of the torque that occurs into the planetary gearbox and/or discharge it from the planetary gearbox. The extended path of the torque flow enables the stiffness and natural frequency of the overall system capable of oscillation having the gearbox shaft to be reduced, thereby making it possible to reduce disturbing oscillations in a planetary gearbox.

Another aspect relates to a data agglomerate with data packets combined in a common file or distributed across different files for representing the three-dimensional design and/or the interactions of all of the constituent parts provided in the gearbox shaft, which can be designed and developed as described above, or the planetary stage, which can be designed and developed as described above, or the wind turbine gearbox, which can be designed and developed as described above, or the drivetrain, which can be designed and developed as described above, wherein the data packets are prepared, upon processing by a data processing device for operating a machine tool for the additive production of devices, to carry out additive manufacturing of the constituent parts of the gearbox shaft or the planetary stage or the wind turbine gearbox or the drivetrain, in particular by 3D printing, and/or upon processing by a data processing device for carrying out a technical simulation, to carry out a simulation of the functioning of the gearbox shaft or the planetary stage or the wind turbine gearbox or the drivetrain and to output simulation results generated in the process for further use, in particular for the purpose of providing fatigue strength verification depending on variable loads and/or variable temperature loadings and/or for the purpose of oscillation analysis, and optionally to compare them with measurement data determined on a device according to the invention produced in reality and/or on a prototype of the device according to the invention.

The data packets of the data agglomerate are specially adapted to the configuration according to the invention of the respective above-described device according to the invention in order to be able to adequately represent the interaction according to the invention of the constituent parts of the device according to the Invention during processing in the data processing device. The data packets may be stored in particular in a spatially distributed manner, but may be adapted to one another in such a way that, in the case that all of the data packets are brought together in a common data processing device, the data agglomerate thus assembled provides all of the required data for additive manufacturing and/or a technical simulation with the aid of the data processing device for the device according to the invention. For example, the data packets are each separate parts of a data library, which are combined for the formation of the data agglomerate and are adapted to one another with respect to their dimensions relative to one another and/or absolute dimensions and/or material properties corresponding to the respective device according to the invention. The data agglomerate can represent a virtual embodiment of the respective device according to the invention in the manner of what is referred to as a “digital twin”, which allows a virtual investigation in the form of a simulation or a real objectification by means of an additive manufacturing process. Such a digital twin is illustrated, for example, in US 2017/286572A1, the disclosure contents of which are hereby referred to as part of the invention.

When the data processing device of the machine tool processes the data agglomerate, the device according to the invention is produced such that, after processing the data agglomerate in the data processing device, the device according to the invention is obtained, at least in the form of a prototype. In particular, a data packet can in each case represent a separately executed constituent part of the respective associated device according to the invention, and therefore the individual constituent parts can be easily actually and/or virtually assembled in their relative position and/or relative movability to realize the interactions that are essential to the invention. In particular, it is possible, with the aid of the respective data packets, to generate the different constituent parts of the respective device separately and optionally from different materials by additive manufacturing and subsequently to assemble them to form a prototype of the respective device. The division of the data of the data agglomerate into different data packets thus makes possible in a simple manner a sequential additive manufacturing of constituent parts, which are movable relative to one another, of the device in question in the form of a kit of parts, which is prepared for the interaction according to the invention of the constituent parts of the prototype for solving the problem on which the invention is based to be assembled merely as expedient.

Additionally or alternatively, it is possible, using the data packets of the data agglomerate, in a virtual environment during a technical simulation, to calculate and/or predict the individual constituent parts of the respective device and their interactions, the physical state and/or the change of physical parameters depending on different boundary conditions and/or over the time of the associated device according to the invention and to continue to use them for checking whether the device according to the invention is suitable enough for the intended use on the basis of the hypothetical configuration and taking into account the hypothetical simulated influences. When the data agglomerate is processed by a data processing device representing the simulation environment, it is possible to be able to investigate the behavior of the device according to the invention, taking into account, in particular, changing, boundary conditions. This makes it possible, for example, to investigate centrifugal force effects on individual components of the device according to the invention depending on different static and/or dynamic loads and/or different operating temperatures, with it being possible for such simulation results to be incorporated into the creation of fatigue strength verification. Preferably, the simulation results obtained after the processing of the data agglomerate in the data processing device for the simulation environment are stored in order to compare them with measurement data determined on a device according to the invention produced in reality and/or on a prototype of the device according to the invention. This makes it possible to assess the quality of the simulation results obtained with the aid of the data agglomerate and/or, in particular in the case of particularly strong deviations, to identify measurement errors and/or an erroneous measurement. Non-destructive quality control of the device according to the invention is thus simplified and improved.

The data agglomerate enables cost-effective production of prototypes and/or computer-based simulations to study the functioning of the rotation body and/or the holding tool, identify problems in the specific application and find improvements. The solution to the problem on which the invention is based can be easily and cost-effectively checked using the data agglomerate.

Below, the invention will be explained by way of example with reference to the appended drawings on the basis of preferred exemplary embodiments, wherein the features presented below may in each case individually or in combination represent an aspect of the invention. If a feature is presented in combination with another feature in the specific exemplary embodiment, this serves only for simplified illustration of the invention using the exemplary embodiment and is in no way intended to mean that this feature cannot also be a development of the invention without the other feature, the scope of protection of the invention being defined by the independent claims. It is shown in:

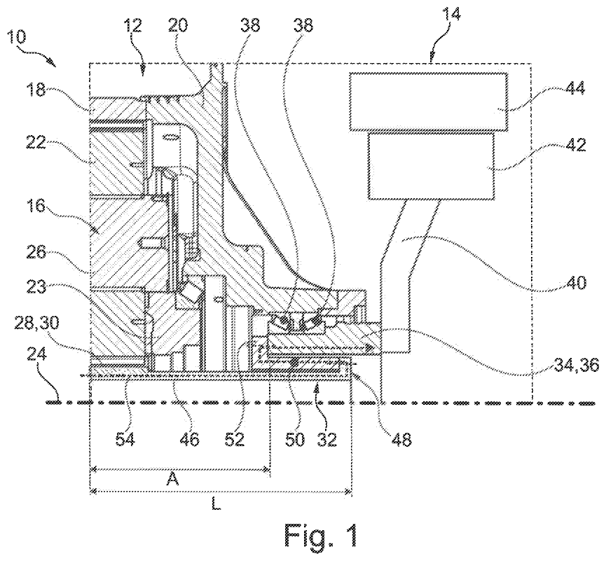

FIG. 1: a schematic sectional view of part of a drivetrain of a wind turbine in a first embodiment,

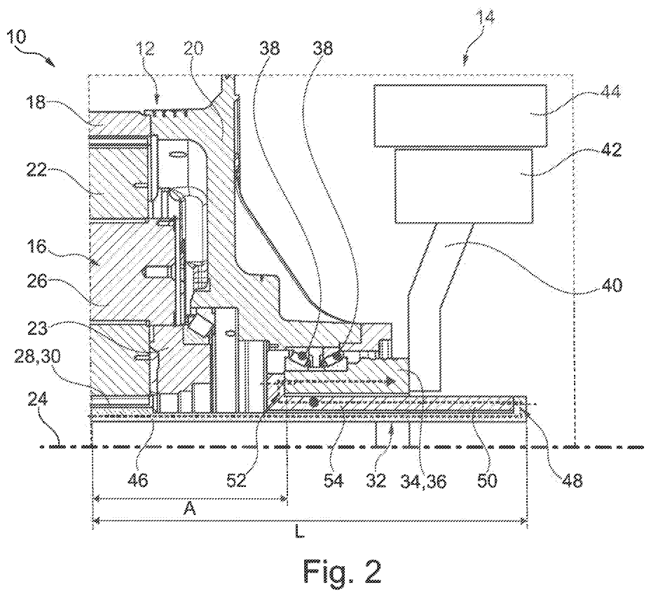

FIG. 2: a schematic sectional view of part of a drivetrain of a wind turbine in a second embodiment, and

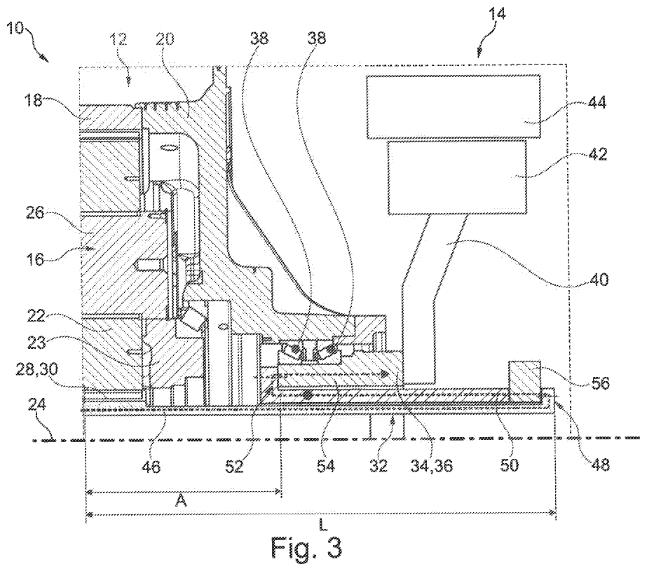

FIG. 3: a schematic sectional view of part of a drivetrain of a wind turbine in a third embodiment.

The drivetrain 10, illustrated in FIG. 1, of a wind turbine can be provided in a nacelle of a tower in order to convert a torque, which originates from a wind rotor that is rotated by wind, in a wind turbine gearbox 12 and to supply a generator 14 for generating electrical energy. The wind turbine gearbox 12 has at least one planetary stage 16, which is in particular a planetary gearbox. The wind turbine gearbox 12 can have two or more planetary stages 16 connected in series, but, for the sake of simplified illustration, only one planetary stage 16 is shown. The planetary stage 16 has a fixed ring gear 18, which can be fixedly connected to a gearbox housing 20 and in particular itself can likewise form part of the gearbox housing 20. At least one planet gear 22 meshes with the ring gear 18, wherein in particular three, four, five or more planet gears 22 can be provided. The at least one planet gear 22 is mounted on a planet carrier 23, which has two side plates, for example, and is spaced apart from a main axis of rotation 24 of the planetary stage 16. In this case, the planet gear 22 can be mounted, for example, via a plain bearing on a planet shaft 26 fixedly fastened to the planet carrier 23, wherein alternatively the planet gear 22 can be fixedly fastened to the planet shaft 26, while the planet shaft 26 can be rotatably mounted in the planet carrier 23. The at least one planet gear 22 meshes with a sun gear 28, which, in the illustrated exemplary embodiment, is simultaneously a first coupling point 30, configured as toothing, of a gearbox shaft 32 configured as a sun shaft. The gearbox shaft 32 is connected to a rotor shaft 34 of the generator 14. In the illustrated exemplary embodiment, the rotor shaft 34 simultaneously represents an output shaft 36 of the wind turbine gearbox 12, which is mounted in the gearbox housing 20 via bearings 38, which are configured in particular as lubricated rolling bearings. The gearbox housing 20 simultaneously axially separates the wind turbine gearbox 12 from the generator 14, so that the gearbox housing 20 simultaneously represents an axial end face of the gearbox housing and an axial end face of a generator housing (not illustrated in any more detail) of the generator 14. The rotor shaft 34 is fixedly connected to a rotor carrier 40, to which a rotor 42 is in turn fixedly connected. The rotor 42 can interact electromagnetically with a stator 44 of the generator 14. For this purpose, the rotor can have permanent magnets, while the stator connected to the generator housing can have electromagnets.

In the exemplary embodiment shown in FIG. 1, the gearbox shaft 32 configured as a sun shaft is formed in multiple parts. The gearbox shaft 32 has a first shaft 46, which forms the first coupling point 30. The first shaft 46 is configured in particular as a hollow shaft. The first shaft 46 is connected, at its axial end that faces away from the first coupling point 30, to a second shaft 50 in a torque-transmitting manner via a rotationally conjoint connection 48, for example flange connection. In the illustrated exemplary embodiment, the second shaft 50 is configured as a hollow shaft, the inner diameter of which is greater than the outer diameter of the first shaft 46. This makes it possible to fit the second shaft 50 onto the first shaft 46 or to fit the first shaft 46 into the second shaft 50. The second shaft 50 extends from the rotationally conjoint connection 48 in the direction of the first coupling point 30, wherein the second shaft is fixedly connected to the part of the rotor shaft 34 acting as the output shaft 36 so as to be spaced apart from the first coupling point 30 and in particular also spaced apart from the planetary stage 16 via a second coupling point 52, in particular a flange connection. A torque flow 54 thus extends along a zigzag-shaped path from the first coupling point 30 to the second coupling point 52, which is significantly greater than a spacing A between the coupling points 30, 52 and an axial total extent L of the gearbox shaft 32. In particular, it is possible to provide further intermediate shafts via a rotationally conjoint connection between the first shaft 46 and the second shaft 50, so that the path of the torque flow 54 is extended even further. In the exemplary embodiment illustrated in FIG. 1, the total extent L of the gearbox shaft 32 ends within the rotor shaft 34, in particular radially within a hub region of the gearbox housing 20 designed for receiving the bearings 38. A common axial sub-region of the gearbox shaft 32, in which the torque flows in the first shaft 46 and in the second shaft 50 flow in opposite axial directions and overlap with one another when viewed in the radial direction, is formed between the rotationally conjoint connection 48 and the second coupling point 52. This common axial sub-region of the gearbox shaft 32 forms a freely oscillating shaft end with an axial extent I of approximately I=L−A. While the rotor shaft 34 is mounted so as to be radially fixed against movement on account of the two axially spaced bearings 38, the common axial sub-region of the gearbox shaft 32 can oscillate elastically in the radial direction with the torque flow flowing in a U shape.

As illustrated in FIG. 2, the gearbox shaft 32 can preferably be inserted into a radially inner interior of the generator 14. In this case, it is possible to make use of the fact that there is sufficient free installation space that is available radially within the rotor 42, in particular radially within the rotor carrier 40 and/or the rotor shaft 34, and can be used by the wind turbine gearbox 12 for a stronger bearing-free protrusion of the gearbox shaft 32 used as a sun shaft. The gearbox shaft 32 can be inserted sufficiently far into the generator 14 that the rotor carrier 40 and/or the rotor 42 can cover part of the gearbox shaft 32 when viewed in the radial direction. As a result, the gearbox shaft 32 is partially arranged in a common axial region with the rotor carrier 40 and/or with the rotor 42. In comparison to the embodiment of the drivetrain 10 illustrated in FIG. 1, in the embodiment of the drivetrain 10 illustrated in FIG. 2, it is possible to achieve a considerably larger total extent L of the gearbox shaft 32 and a considerably longer path for the torque flow 54 with an identical spacing A between the coupling points 30, 52. A common axial sub-region of the gearbox shaft 32, in which the torque flows in the first shaft 46 and in the second shaft 50 flow in opposite axial directions and overlap with one another when viewed in the radial direction, is formed in turn between the rotationally conjoint connection 48 and the second coupling point 52. This common axial sub-region of the gearbox shaft 32 forms a freely oscillating shaft end with an axial extent I of approximately I=L−A. While the rotor shaft 34 is mounted so as to be radially fixed against movement on account of the two axially spaced bearings 38, the common axial sub-region of the gearbox shaft 32 can oscillate elastically in the radial direction with the torque flow flowing in a U shape.

In the embodiment of the drivetrain 10 illustrated in FIG. 3, in comparison to the embodiment of the drivetrain 10 illustrated in FIG. 2, it is possible to make further use of the installation space within the generator and the good accessibility on the generator side by virtue of a coupling element 56, in particular in the form of an elastic coupling, being provided between the first shaft 46 and the second shaft 50 or an intermediate shaft (not illustrated), interposed therebetween. As a result, the oscillation properties of the gearbox shaft 32 can be further positively influenced. A common axial sub-region of the gearbox shaft 32, in which the torque flows in the first shaft 46 and in the second shaft 50 flow in opposite axial directions and overlap with one another when viewed in the radial direction, is formed in turn between the rotationally conjoint connection 48 and the second coupling point 52. This common axial sub-region of the gearbox shaft 32 forms a freely oscillating shaft end with an axial extent I of approximately I=L−A. While the rotor shaft 34 is mounted so as to be radially fixed against movement on account of the two axially spaced bearings 38, the common axial sub-region of the gearbox shaft 32 can oscillate elastically in the radial direction with the torque flow flowing in a U shape.

In the embodiments of the drivetrain 10 illustrated in FIG. 1, FIG. 2 and FIG. 3, the gearbox shaft 32 is connected from the gearbox side to the rotor shaft 34 and the rotor carrier 40. However, it is possible that the gearbox shaft 32 is directly or indirectly connected to the rotor carrier 40 on the gearbox side, i.e. the second coupling point in FIG. 1, FIG. 2 and/or FIG. 3 is provided in the axial direction to the right of the rotor carrier 40. In particular, the rotor shaft 34 can protrude axially from the rotor carrier 40 in the direction of the wind turbine gearbox 12 and, as illustrated in FIG. 1, FIG. 2 and/or FIG. 3, can be similarly mounted in a radially fixed manner.

In a departure from the embodiments of the drivetrain 10 shown in FIG. 1, FIG. 2 and FIG. 3, the second shaft 50 can extend from the rotationally conjoint connection 48 significantly beyond the axial region of the bearings 38, if particular if sufficient axial space is kept free between the rotor shaft 34 and the planet carrier 23. In this case, the second shaft 50 can be connected, via a further rotationally conjoint connection (not illustrated), which forms a disk region of the gearbox shaft, to a third (hollow) shaft (not illustrated), which radially extends outside the second shaft 50 in the axial direction back to the rotor shaft 34 and can be fastened to the rotor shaft 34 via the second coupling point 52. This results, in addition to or as an alternative to the shaft end freely oscillating in the direction of the generator 14, in a further freely oscillating shaft end, which is in a common axial sub-region between the gearbox-side rotationally conjoint connection (not illustrated) and the second coupling point 52, wherein, in this sub-region, the torque flows in the second shaft 50 and in the third shaft (not illustrated) likewise flow in opposite axial directions and overlap with one another when viewed in the radial direction. It is also possible to fasten the third shaft between the rotor shaft 34 and the rotor carrier 40 to the rotor carrier 40 via the second coupling point 52 or to fasten the third shaft, on the axial side with the rotor carrier 40 facing away from the rotor shaft 34, to the rotor carrier 40 via the second coupling point 52. This makes it possible to use axial and radial installation space to form another freely oscillating shaft end and to set its freely oscillating axial extent via a correspondingly selected axial fastening location for fastening to the rotor carrier 40.

1-15. (canceled)

16. A gearbox shaft, in particular a sun shaft, for a planetary gearbox, the gearbox shaft comprising:
a first coupling point, in particular toothing, for introducing a torque;
a first shaft region designed to transmit the torque along an axial torque flow;
a second shaft region designed to transmit the torque along an axial torque flow counter to the first shaft region;
a disk region designed to transmit the torque between the first shaft region and the second shaft region along a radial torque flow; and
a second coupling point designed to discharge the torque, in particular to a rotor shaft of a generator,
wherein a path of a torque flow extending from the first coupling point to the second coupling point is formed,
wherein a sum of axial components of the path along which the torque flow flows is greater than an axial spacing between the first coupling point and the second coupling point,
wherein the first shaft region and the second shaft region, when viewed in an axial direction, overlap in a common axial sub-region,
wherein a freely oscillating shaft end is formed in the common axial sub-region in which the torque flow flows at different radil in opposite axial directions, and
wherein the disk region defines an axial end portion that is part of the freely oscillating shaft end.

17. The gearbox shaft of claim 16, wherein the path of the torque flow and the spacing between axial sides facing away from one another of the first coupling point and the second coupling point are governed by 1.1≤W/A≤12.0, in particular 1.5≤W/A≤6.0, preferably 2.0≤W/A≤4.0 and particularly preferably 2.5≤W/A≤3.0, wherein W is the path, and A is the spacing.

18. The gearbox shaft of claim 16, wherein a total extent of the gearbox shaft is greater than the spacing between axial sides facing away from one another of the first coupling point and the second coupling point is governed by 1.01≤L/A≤6.0, in particular 1.05≤L/A≤4.0, preferably 1.10≤L/A≤2.0 and particularly preferably 1.25≤L/A≤1.75, wherein L is the total extent of the gearbox shaft, and A is the spacing.

19. The gearbox shaft of claim 16, further comprising:
a first shaft directly connected to the first coupling point;
a second shaft which is different from the first shaft and directly connected to the second coupling point; and
an intermediate shaft,
wherein the second shaft is connected directly or indirectly, in particular via the intermediate shaft, for conjoint rotation with the first shaft,
wherein the first shaft and the second shaft, when viewed in a radial direction, at least partially overlap in a common axial region,
wherein, in particular, the intermediate shaft is arranged within the common axial region in the radial direction between the first shaft and the second shaft in the radial direction.

20. The gearbox shaft of claim 19, wherein the first shaft has an outer diameter and the second shaft has an outer diameter, wherein, for a ratio V defined as d1/d2 or d2/d1, 1.01≤V≤5.0, in particular 1.05≤V≤3.0, preferably 1.10≤V=2.0 and particularly preferably 1.25≤V≤1.5, wherein d1 is the outer diameter of the first shaft, and d2 is the outer diameter of the second shaft.

21. The gearbox shaft of claim 19, wherein a connection of the first shaft for conjoint rotation with the second shaft or with the intermediate shaft in the axial direction is formed outside an axial region of the first coupling point and the second coupling point and outside an axial interspace between the first coupling point and the second coupling point.

22. The gearbox shaft of claim 21, wherein the first shaft is formed axially adjacent to the first coupling point and/or the second shaft is formed axially adjacent to the second coupling point and in each case is formed as a hollow shaft with a wall thickness axially adjacent to the connection for conjoint rotation, wherein, with respect to a length of the first shaft and/or the second shaft outside a respective of the first and second coupling points and outside the connection for conjoint rotation, 0.01≤s/l≤0.50, in particular 0.02≤s/l≤0.25, preferably 0.03≤s/l≤0.15 and particularly preferably 0.05≤s/l≤0.10, wherein s is the wall thickness, and l is the length of the first shaft and/or the second shaft.

23. The gearbox shaft of claim 19, further comprising an elastically deformable damper element and/or an, in particular switchable and/or controllable, coupling element to contact the first shaft and the second shaft or the intermediate shaft and/or the second shaft and the intermediate shaft.

24. The gearbox shaft of claim 19, further comprising an electrical insulating material formed between the first coupling point and the second coupling point within the torque flow, wherein in particular at least one of the second shaft and the intermediate shaft is produced entirely or at least in certain portions from the electrically insulating material.

25. The gearbox shaft of claim 16 for use in a planetary gearbox for reducing audible structure-borne noise and/or airborne noise and/or resonance oscillations.

26. A planetary stage, in particular a planetary gearbox, the planetary stage comprising the gearbox shaft of claim 16, wherein the first coupling point is arranged in a common axial region with planet gears and/or a ring gear of the planetary stage and the second coupling point is arranged so as to be axially spaced apart from the planet gears and/or the ring gear.

27. A wind turbine gearbox for speed conversion in a drivetrain of a wind turbine, the wind turbine gearbox comprising:
a planetary stage comprising the gearbox shaft of claim 16, wherein the first coupling point is arranged in a common axial region with planet gears and/or a ring gear of the planetary stage and the second coupling point is arranged so as to be axially spaced apart from the planet gears and/or the ring gear; and
a gearbox housing, designed, when viewed in a radial direction of the gearbox shaft, to only partially cover the gearbox shaft and to cover both the first coupling point and the second coupling point of the gearbox shaft.

28. A drivetrain for a wind turbine, the drivetrain comprising”
the wind turbine gearbox of claim 26 for converting a torque introducible by a wind rotor and a generator, which is coupled to the wind turbine gearbox, for generating electrical energy from the torque flow introduced by the wind turbine gearbox, wherein, in particular, the torque flow in its entirety is introduced into the generator passes via the gearbox shaft.

29. The drivetrain of claim 28, wherein part of the gearbox shaft of the wind turbine gearbox protrudes into the generator, said first coupling point being provided in the wind turbine gearbox, and said second coupling point being provided within the wind turbine gearbox or within the generator.

30. A data agglomerate, comprising data packets combined in a common file or distributed across different files for representing a three-dimensional design and/or interactions of all constituent parts in a gearbox shaft or a planetary stage or a wind turbine gearbox or a drivetrain, said data packets being prepared so as upon processing by a data processing device for operating a machine tool for additive manufacturing of devices, to carry out additive production of the constituent parts of the gearbox shaft or the planetary stage or the wind turbine gearbox or the drivetrain, in particular by 3D printing, and/or
upon processing by a data processing device for carrying out a technical simulation, to carry out a simulation of a functioning of the gearbox shaft or the planetary stage or the wind turbine gearbox or the drivetrain and to output simulation results generated for further use, in particular for providing fatigue strength verification depending on variable loads and/or variable temperature loadings and/or for oscillation analysis.
